(19) United States
(12) Patent Application Publication
(10) Pub. No.: US 2026/0136727 A1
(43) Pub. Date: May 14, 2026

(54) MICROPARTICLE ARRANGEMENTS IN LIGHT-EMITTING DIODE PACKAGES AND RELATED METHODS

(71) Applicant: CreeLED, Inc., Durham, NC (US)

(72) Inventors: David Suich, Durham, NC (US); Michael Check, Holly Springs, NC (US); Andre Pertuit, Raleigh, NC (US); Joseph G. Sokol, Durham, NC (US); Robert Wilcox, Rolesville, NC (US); Colin Blakely, Raleigh, NC (US)

(21) Appl. No.: 18/942,908

(22) Filed: Nov. 11, 2024

(51) Int. Cl. H01L 33/58; H01L 33/50; H01L 33/54

(52) U.S. Cl. CPC H10H 20/855; H10H 20/8512; H10H 20/853; H10H 20/0361; H10H 20/0363

(57) ABSTRACT

Solid-state lighting devices including light-emitting diodes (LEDs) and more particularly microparticle arrangements in LED packages are disclosed. Microparticles and corresponding microparticle layers are structured to internally recirculate light received from an LED chip and/or a recipient lumiphoric material layer to promote increased color mixing and color over angle uniformity. Microparticles are structured with particle sizes that exceed wavelengths of light provided by LED chips and/or lumiphoric materials to elicit internal recirculating of light. Arrangements and/or particle sizes of microparticles are disclosed that tailor light recycling and color mixing to various applications with targeted emission patterns. Related methods include forming microparticles and corresponding microparticle layers before encapsulants of LED packages.

### FIELD OF THE DISCLOSURE

The present disclosure relates to solid-state lighting devices including light-emitting diodes (LEDs) and more particularly to microparticle arrangements in LED packages and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Modern LEDs have enabled a variety of new display applications and are being increasingly utilized for general illumination applications.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions. Lumiphoric materials may be arranged such that at least some light generated from the active regions of LED chips is converted to a different wavelength.

LED packages have been developed that provide mechanical support, electrical connections, and encapsulation for LED emitters and lumiphoric materials. As LED technology continues to advance, LED chips and related packages are needed that emit light of high color quality for various applications. Despite recent advances in LED technology, challenges remain for producing high quality light with desired emission characteristics while also providing high light emission efficiency in LED chips and packages.

The art continues to seek improved LEDs and solid-state lighting devices having desirable illumination characteristics capable of overcoming challenges associated with conventional LED devices.

### SUMMARY

The present disclosure relates to solid-state lighting devices including light-emitting diodes (LEDs) and more particularly to microparticle arrangements in LED packages and related methods. Microparticles and corresponding microparticle layers are structured to internally recirculate light received from an LED chip and/or a recipient lumiphoric material layer to promote increased color mixing and color over angle uniformity. Microparticles are structured with particle sizes that exceed wavelengths of light provided by LED chips and/or lumiphoric materials to elicit internal recirculating of light. Arrangements and/or particle sizes of microparticles are disclosed that tailor light recycling and color mixing to various applications with targeted emission patterns. Related methods include forming microparticles and corresponding microparticle layers before encapsulants of LED packages.

In one aspect, an LED package comprises: a support element; an LED chip on the support element, the LED chip configured to emit light with a first peak wavelength; a lumiphoric material layer on the LED chip, the lumiphoric material layer configured to convert at least a portion of the light of the first peak wavelength to light with a second peak wavelength that is different than the first peak wavelength; and a microparticle layer on the lumiphoric material layer, the microparticle layer comprising a plurality of microparticles with an average particle size in a range from above 1 micron (μm) to 1000 μm.

The LED package may further comprise an encapsulant on the microparticle layer. In certain embodiments, the encapsulant forms a lens over the LED chip, and the encapsulant further forms an extension that laterally extends from a boundary of the lens to a peripheral edge of the support element, and a portion of the microparticle layer is covered by the extension. In certain embodiments, the microparticle layer further comprises a host material and the plurality of microparticles is positioned within the host material, wherein the host material comprises a different index of refraction than the encapsulant. The LED package may further comprise a coating on the plurality of microparticles, wherein the coating comprises a different index of refraction than the encapsulant. In certain embodiments, the coating forms a dielectric shell on each microparticle of the plurality of microparticles. In certain embodiments, the plurality of microparticles are positioned between the coating and the lumiphoric material layer, and one or more air gaps are formed between the plurality of microparticles and the lumiphoric material layer. In certain embodiments, at least one microparticle of the plurality of microparticles is arranged to protrude out of a surface of the encapsulant.

In certain embodiments, the plurality of microparticles forms a single monolayer for the microparticle layer. In certain embodiments, the plurality of microparticles are arranged with a hexagonal close packing arrangement for the single monolayer. In certain embodiments: the plurality of microparticles comprises a first distribution of microparticles and a second distribution of microparticles; a first average particle size of the first distribution of microparticles is larger than a second average particle size of the second distribution of microparticles; and the first distribution of microparticles is positioned closer to the lumiphoric material layer than the second distribution of microparticles. In certain embodiments, the plurality of microparticles comprises a plurality of microspheres. In certain embodiments, the plurality of microparticles comprise glass, polyethylene, polystyrene, or polymethyl methacrylate. In certain embodiments, the plurality of microparticles form at least one localized region of microparticles on a surface of the lumiphoric material layer, and another surface of the lumiphoric material layer is devoid of the plurality of microparticles. In certain embodiments, at least one microparticle of the plurality of microparticles comprises one or more internal voids. In certain embodiments, at least two microparticles of the plurality of microparticles are merged together. In certain embodiments, at least one microparticle of the plurality of microparticles is partially embedded within the lumiphoric layer.

In another aspect, an LED package comprises: a support element; an LED chip on the support element, the LED chip configured to emit light with a first peak wavelength; an encapsulant on the LED chip; and a plurality of microparticles in the encapsulant, wherein at least one microparticle of the plurality of microparticles is arranged to protrude out of a surface of the encapsulant. In certain embodiments, an average particle size is in a range from above 100 micron (μm) to 1000 μm. The LED package may further comprise a lumiphoric material layer on the LED chip, the lumiphoric material layer configured to convert at least a portion of the light of the first peak wavelength to light with a second peak wavelength that is different than the first peak wavelength, wherein at least one other microparticle of the plurality of microparticles is in contact with the lumiphoric material layer. In certain embodiments, the support element comprises a lead frame structure. In certain embodiments, at least two microparticles of the plurality of microparticles are merged together.

In another aspect, a method of forming an LED package comprises: mounting an LED chip on a support element, the LED chip configured to emit light with a first peak wavelength; forming a lumiphoric material layer on the LED chip, the lumiphoric material layer configured to convert at least a portion of the light of the first peak wavelength to light with a second peak wavelength that is different than the first peak wavelength; forming a microparticle layer on the lumiphoric material layer; and forming an encapsulant on the microparticle layer after forming the microparticle layer. In certain embodiments, forming the microparticle layer comprises arranging a plurality of microparticles on the lumiphoric material layer and heating the plurality of microparticles such that at least two microparticles of the plurality of microparticles merge together

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a cross-sectional view of an exemplary light-emitting diode (LED) package with a lumiphoric material layer.

FIG. 1B is a view of a portion of the LED package of FIG. 1A illustrating variation in light paths through the lumiphoric material layer.

FIG. 2A is a cross-sectional view of an LED package similar to the LED package of FIG. 1A and further including a microparticle layer according to aspects of the present disclosure.

FIG. 2B is a view of a portion of the LED package of FIG. 2A illustrating variation in light paths through the lumiphoric material layer and the microparticle layer.

FIG. 3 is a cross-sectional view of an LED package similar to the LED package of FIGS. 2A and 2B illustrating a generally uniform particle size distribution.

FIG. 4 is a cross-sectional view of an LED package similar to the LED package of FIG. 3 for embodiments with a larger variation in particle size distribution for the microparticles.

FIG. 5 is a cross-sectional view of an LED package similar to the LED package of FIG. 3 for embodiments where the microparticle layer comprises a host material that encapsulates the microparticles.

FIG. 6 is a cross-sectional view of an LED package similar to the LED package of FIG. 3 for embodiments where the microparticles comprise a coating on each microparticle.

FIG. 7 is a cross-sectional view of an LED package similar to the LED package of FIG. 6 for embodiments where the coating is formed on the microparticles after the microparticles are positioned on the lumiphoric material layer.

FIG. 8 is a cross-sectional view of an LED package similar to the LED package of FIG. 3 for embodiments where the microparticles are patterned as localized regions on portions of the lumiphoric material layer.

FIG. 9 is a cross-sectional view of an LED package similar to the LED package of FIG. 8 for embodiments where the microparticles form an alternative pattern on the lumiphoric material layer.

FIG. 10A is a cross-sectional view of an LED package similar to the LED package of FIG. 3 for embodiments where portions of the microparticles are arranged to protrude out of the encapsulant.

FIG. 10B is a cross-sectional view of the LED package of FIG. 10A for embodiments where one or more of the microparticles are in contact with one another.

FIG. 11 is a cross-sectional view of an LED package similar to the LED package of FIGS. 10A and 10B for embodiments where the support element comprises a lead frame structure.

FIG. 12 is a cross-sectional view of an LED package similar to the LED package of FIG. 11 for embodiments where additional microparticles are arranged within the encapsulant.

FIG. 13 is a cross-sectional view of an LED package similar to the LED package of FIG. 12 for embodiments wherein the microparticles are arranged in a conformal manner on the lumiphoric material layer.

FIG. 14 is a cross-sectional view of a microparticle for embodiments where the microparticle forms a spherical shape, such as a microsphere.

FIG. 15 is a cross-sectional view of a microparticle for embodiments where the microparticle forms an oblong shape.

FIG. 16 is a cross-sectional view of a microparticle for embodiments where the microparticle includes one or more internal voids.

FIG. 17 is a cross-sectional view of a microparticle for embodiments where the microparticle includes a coating in the form of an outer shell.

FIG. 18 is a top view of a layout of the microparticle layer according to principles of the present disclosure.

FIG. 19A is a cross-sectional view of the LED package of FIG. 3 at a fabrication step after the LED chip is mounted to the support element, followed by formation of the light-altering material and the lumiphoric material layer.

FIG. 19B is a cross-sectional view of the LED package of FIG. 19A at a subsequent fabrication step where the microparticle layer is formed.

FIG. 19C is a cross-sectional view of the LED package of FIG. 19B at a subsequent fabrication step where the encapsulant is formed on the previously formed microparticle layer.

FIG. 20A is a cross-sectional view of the microparticle layer for any of the previous embodiments at an initial fabrication step where neighboring microparticles are spaced from one another.

FIG. 20B is a cross-sectional view of the microparticle layer of FIG. 20A at a subsequent processing step where neighboring microparticles begin to merge together.

FIG. 20C is a cross-sectional view of the microparticle layer of FIG. 20B with additional merging of microparticles

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to microparticle arrangements in LED packages. Microparticles and corresponding microparticle layers are structured to internally recirculate light received from an LED chip and/or a recipient lumiphoric material layer to promote increased color mixing and color over angle uniformity. Microparticles are structured with particle sizes that exceed wavelengths of light provided by LED chips and/or lumiphoric materials to elicit internal recirculating of light. Arrangements and/or particle sizes of microparticles are disclosed that tailor light recycling and color mixing to various applications with targeted emission patterns. Related methods include forming microparticles and corresponding microparticle layers before encapsulants of LED packages.

Before delving into specific details of the present disclosure, an overview of various elements that may be included in exemplary LED devices of the present disclosure is provided for context. An LED chip typically includes an active LED structure or region with various semiconductor layers. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may generally include an active layer sandwiched between n-type and p-type oppositely doped epitaxial layers, all of which are formed successively on a growth substrate. It is understood that additional layers and elements may also be included in the active LED structure, including, but not limited to, buffer layers, nucleation layers, super lattice structures, undoped layers, cladding layers, contact layers, current-spreading layers, and light extraction layers and elements. The active layer can comprise a single quantum well, a multiple quantum well, a double heterostructure, or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure may emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. Other wavelength ranges include a range from 400 nm to about 430 nm and/or a range from 480 nm to 500 nm, among others, or any wavelength in a range from 400 nm to 750 nm. In certain embodiments, the active LED structure may be configured to emit light that is outside the visible spectrum, including infrared (IR) or one or more portions of the ultraviolet (UV) spectrum. The IR spectrum may encompass wavelengths from 700 nm to 1000 nm. The UV spectrum is typically divided into three wavelength range categories denotated with letters A, B, and C. UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs may also be provided with one or more lumiphoric materials to provide LED packages with aggregated emissions having a broad spectrum and improved color quality for visible light applications.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure may be useful for LED chips having a variety of geometries, including flip-chip geometries. Flip-chip structures for LED chips typically include anode and cathode connections that are provided from a same side or face of the LED chip. The anode and cathode side is typically structured as a mounting face of the LED chip for flip-chip mounting to another surface, such as a printed circuit board. In this regard, the anode and cathode connections on the mounting face serve to mechanically bond and electrically couple the LED chip to the other surface. When flip-chip mounted, the opposing side or face of the LED chip corresponds with a light-emitting face that is oriented toward an intended emission direction. In certain embodiments, a growth substrate for the LED chip may form and/or be adjacent to the light-emitting face when flip-chip mounted. During chip fabrication, the active LED structure may be epitaxially grown on the growth substrate. Other applicable LED chip geometries include vertical with anode and cathodes on opposing sides, and/or structures where growth substrates are removed and active LED structures are supported by carrier substrates.

LED chips as described herein may be well suited for placement in LED packages that may include one or more elements, such lumiphoric materials or phosphors for wavelength conversion, encapsulants, light-altering materials, lenses, and electrical contacts, among others, that are provided with one or more LED chips. Such LED packages may include a support structure or member, such as a submount or a lead frame. A support structure may refer to a structure of an LED package that supports one or more other elements of the LED package, including but not limited to LED chips, lumiphoric materials, and/or encapsulants. In certain embodiments, a support structure may include a submount on which an LED chip is mounted. Suitable materials for a submount include, but are not limited to, ceramic materials such as aluminum oxide or alumina, AlN, or organic insulators like polyimide (PI) and polyphthalamide (PPA). In other embodiments a submount may comprise a printed circuit board (PCB), sapphire, Si, or any other suitable material. For PCB embodiments, different PCB types can be used such as standard FR-4 PCB, metal core PCB, or any other type of PCB.

In still further embodiments, the support structure may embody a lead frame structure. Lead frame structures typically include a lead frame at least partially encased by a body or housing. A lead frame may typically be formed of a metal, such as copper, copper alloys, or other conductive metals. The lead frame structure may initially be part of a larger structure that is singulated during the manufacturing of individual LED packages. Within an individual LED package, isolated portions of the lead frame may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. In certain embodiments, one or more lumiphoric materials, such as phosphor particles, may be integrated or otherwise embedded within the encapsulant material.

Light-altering materials may be arranged within LED packages to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Lumiphoric materials (also referred to herein as luminophores) are positioned to receive and absorb at least some of the light from an LED chip and convert such light to one or more different wavelength spectra according to the characteristic emission from the lumiphoric materials. In this regard, at least one luminophore receiving at least a portion of the light generated by the LED chip may re-emit light having a different peak wavelength than the LED source. An LED chip and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of from 2500 Kelvin (K) to 10,000 K. In certain embodiments, lumiphoric materials having cyan, green, amber, yellow, orange, and/or red peak wavelengths may be used. In certain embodiments, the combination of the LED chip and the one or more luminophores (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. In still further embodiments, an LED chip may be configured to emit light outside the visible spectrum, such as UV light, and the lumiphoric materials may convert at least a portion of the UV light to visible light. In other embodiments, the LED chip may be configured to emit visible light and lumiphoric materials may be provided that convert at least a portion of the visible light to IR or UV wavelengths.

Lumiphoric materials as described herein may be or include one or more of a phosphor, a scintillator, a lumiphoric ink, a quantum dot material, and the like. Lumiphoric materials may be provided by any suitable means, for example, dispersal of particles in a host material or binder such as an encapsulant material. In certain embodiments, lumiphoric materials may be downconverting or upconverting, and combinations of both downconverting and upconverting materials may be provided. In certain embodiments, multiple different (e.g., compositionally different) lumiphoric materials that are arranged to produce different peak wavelengths may be arranged to receive emissions from one or more LED chips. In certain embodiments, one or more lumiphoric materials may be arranged in a substantially uniform manner. In other embodiments, one or more lumiphoric materials may be arranged in a manner that is non-uniform with respect to one or more of material composition, concentration, and thickness. In certain embodiments, the loading percentage of one or more lumiphoric materials may be varied relative to one or more positions of an LED chip. In certain embodiments, one or more lumiphoric materials may be patterned to include one or more stripes, dots, curves, or polygonal shapes. In certain embodiments, multiple lumiphoric materials may be arranged in different discrete regions or discrete layers for an LED chip.

In certain LED packages, a lumiphoric material is typically arranged to convert a portion of light from an underlying LED chip to a different wavelength, and aggregate emissions include a mixture of light from the LED chip and light subjected to wavelength conversion by the lumiphoric material. The amount of light subject to wavelength conversion may be a function of various factors, including lumiphoric material loading and/or a thickness of the layer or encapsulant that forms the lumiphoric material. Moreover, a path length of light traversing through a lumiphoric material layer may further contribute to how much light is subject to wavelength conversion. For example, a longer path length of light may correspond with increased wavelength conversion. As described above, light generated within an LED chip is typically initiated in multiple directions. Accordingly, light from the LED chip may propagate through a lumiphoric material layer in a variety of angles relative to the LED chip. For a same or similar thickness of a lumiphoric material layer, light from the LED chip that propagates in a direction normal to the surface of the LED chip may have a shorter path length through the lumiphoric material layer than light with increasing angles relative to the normal direction. Such variations in path lengths may correspond with variations in color over angle in LED packages.

According to aspects of the present disclosure, arrangements of microparticles are described that recirculate light from the LED chip and/or lumiphoric material layer to promote increased color mixing and reduced color over angle nonuniformity. Microparticles are structured with particle sizes that exceed wavelengths of light provided by LED chips and/or lumiphoric materials. With increased particle size, light from LED chips and/or lumiphoric materials may propagate within an individual microparticle and refract a number of times before exiting, thereby internally recirculating light before passing light with increased mixing across a variety of angles. In this regard, microparticles according to the present disclosure may effectively form individual light-mixing chambers that may be positioned in various locations within an LED package. In contrast, smaller particle sizes may typically form light-scattering and/or light-diffusing particles that do not exhibit multiple internal refractions. According to aspects of the present disclosure, microparticles may have particle sizes in a range from above 1 micron (μm) to 1000 μm, or in a range from 100 μm to 1000 μm, well above wavelengths in the visible light spectrum typically provided by LED chips and lumiphoric materials. Moreover, average particle sizes for a distribution of microparticles may be in the range from above 1 μm to 1000 μm, or in a range from 100 μm to 1000 μm. Exemplary materials for microparticles include glass and various polymers, such as polyethylene, polystyrene, and/or polymethyl methacrylate (PMMA). In certain embodiments, microparticles comprise microspheres where the above particle sizes correspond with diameters.

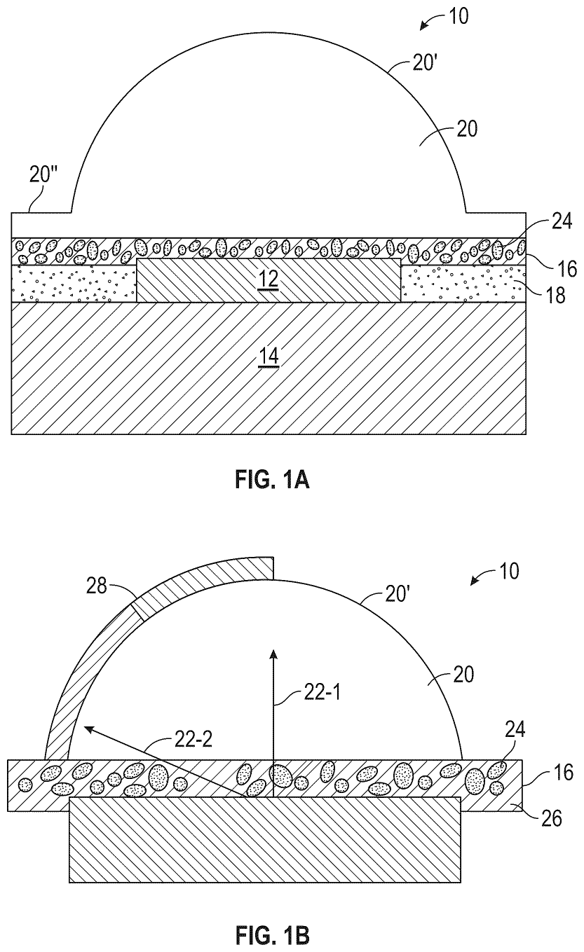

FIG. 1A is a cross-sectional view of an exemplary LED package 10. The LED package 10 includes an LED chip 12 on a support element 14, such as a submount structure or a lead frame structure. A lumiphoric material layer 16 is provided on a top surface of the LED chip 12 opposite the support element 14. In certain embodiments, a light-altering material 18, such as a light-reflective material, may be arranged on the support element 14 and about peripheral edges of the LED chip 12. In this arrangement, the light-altering material 18 is positioned to redirect laterally propagating light from the LED chip 12 towards the lumiphoric material layer 16. An encapsulant 20 may cover and encapsulate the LED chip 12 on the support element 14. In certain embodiments, the encapsulant 20 may form a lens 20′ configured to direct emissions exiting the LED package 10. The lens 20′ may form a shape including hemispheric, ellipsoid, ellipsoid bullet, cubic, flat, hex-shaped or square. In certain embodiments, another suitable shape for the lens 20′ includes both curved and planar surfaces, such as a hemispheric or curved top portion with planar side surfaces. The encapsulant 20 may further form an extension 20″ that laterally extends from a perimeter boundary of the lens 20′ to one or more perimeter edges of the support element 14. The extension 20″ may form a generally planar portion of the encapsulant 20 that covers portions of the submount outside a boundary of the lens 20′.

FIG. 1B is a view of a portion of the LED package 10 of FIG. 1A illustrating variation in light paths 22-1, 22-2 through the lumiphoric material layer 16. As illustrated, the lumiphoric material layer 16 may embody a lumiphoric material layer that includes lumiphoric particles 24, such as phosphor particles, suspended in a binder material 26, such as silicone. The light path 22-1 is provided in a direction generally normal to the top surface of the LED chip 12 while the light path 22-2 is in a direction with an increased angle relative to the normal direction. The light path 22-1 has a shorter distance to travel through the lumiphoric material layer 16 as compared to the wider angle formed by the light path 22-2. In FIG. 1B, a portion of a color over angle emission profile 28 that exits the LED package 10 is superimposed over the lens 20'. Light propagating with the longer light path 22-2 may accordingly be subject to increased wavelength conversion such that wider angle portions of the emission profile 28 exhibit different colors as compared with light propagating along the shorter light path 22-1. In the example of the LED chip 12 generating blue light and the lumiphoric material layer 16 generating yellow light, the light along the light path 22-2 will have increased concentrations of yellow light as compared with light along the light path 22-1.

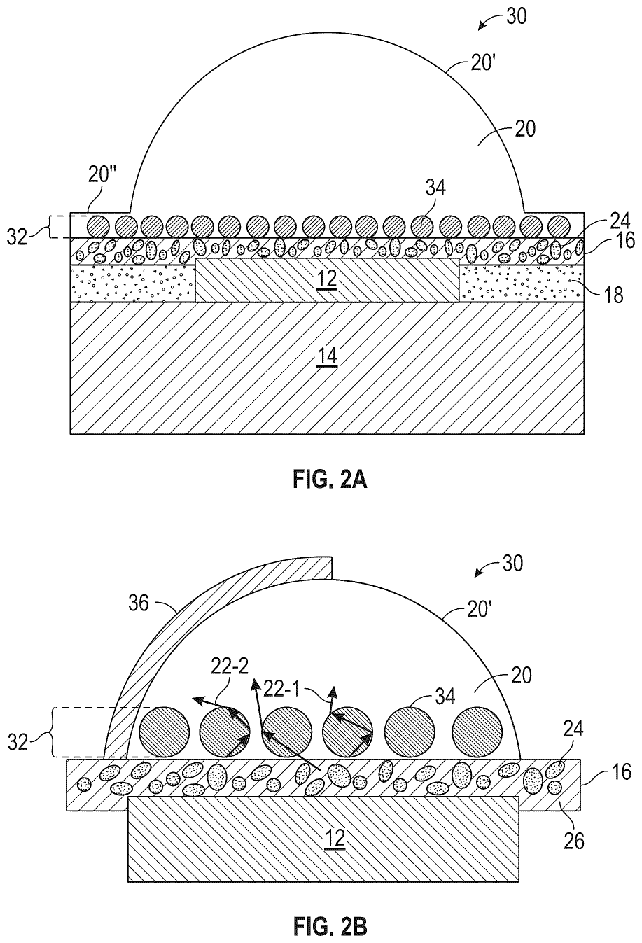

FIG. 2A is a cross-sectional view of an LED package 30 similar to the LED package 10 of FIG. 1A and further including a microparticle layer 32 according to aspects of the present disclosure. In certain embodiments, the microparticle layer 32 comprises microparticles 34 arranged on the lumiphoric material layer 16. By positioning the microparticle layer 32 proximate or even in contact with the lumiphoric material layer 16, at least a portion of light exiting the lumiphoric material layer 16 may enter one or more of the microparticles 34 with reduced interaction with the encapsulant 20. In further embodiments, one or more of the microparticles 34 may contact and be partially embedded in the lumiphoric material layer 16. In certain embodiments, a portion of the microparticle layer 32 is covered by the extension 20″ of the encapsulant 20 proximate perimeter edges of the support element 14. In this manner, light that may guide along the extension 20″ may also be subject to enhanced light mixing. In certain embodiments, the microparticle layer 32 is deposited on the lumiphoric material layer 16 before the encapsulant 20 is formed. As such, the microparticles 34 may be precisely located in contact with the lumiphoric material layer 16, and the encapsulant 20 may effectively encapsulate the microparticles 34 in place.

FIG. 2B is a view of a portion of the LED package 30 of FIG. 2A illustrating variation in light paths 22-1, 22-2 through the lumiphoric material layer 16. For illustrative purposes, the microparticles 34 are scaled larger to illustrate the various light paths 22-1, 22-2. A color over angle emission profile 36 that exits the LED package 30 is superimposed over the lens 20′. As illustrated, light may follow one light path 22-1 that enters and internally reflects a number of times within an individual microparticle 34 before exiting in a direction close to normal from a surface of the LED chip 12. Light may follow another light path 22-2 that enters and internally reflects a number of times within another individual microparticle 34 before exiting in a direction with a wider angle relative to normal from the surface of the LED chip 12. Accordingly, light from the LED chip 12 and the lumiphoric material layer 16 may experience light recirculation and mixing within individual microparticles 34 across the LED chip 12 before exiting the microparticles 34 within increased color mixing. The color over angle emission profile 36 of the LED package 30 thereby exhibits greater uniformity in comparison to the color over angle emission profile 28 for the LED package 10 of FIG. 1B. In certain embodiments, the size and/or shape of the microparticles 34 may be configured to elicit whispering gallery modes of light where the light circulates along curved surfaces of the microparticles 34 before escaping with increased color mixing.

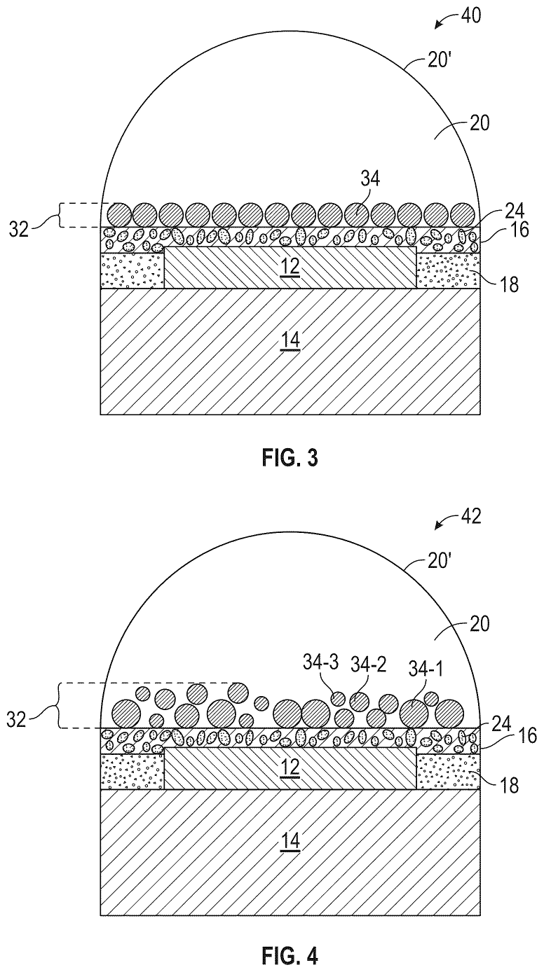

FIG. 3 is a cross-sectional view of an LED package 40 similar to the LED package 30 of FIGS. 2A and 2B. In a similar manner as illustrated with respect to FIGS. 2A and 2B, the microparticles 34 of the LED package 40 are formed with a generally uniform particle size distribution. With a uniform particle size distribution, the microparticles 34 of the microparticle layer 32 may be tighter packed relative to one another to provide controlled light mixing across the LED chip 12 and lumiphoric material layer 16. Moreover, the uniform dimensions of the microparticles 34 allow the microparticle layer 32 to be formed as a single monolayer of microparticles 34 in certain embodiments.

FIG. 4 is a cross-sectional view of an LED package 42 similar to the LED package 40 of FIG. 3 for embodiments with a larger variation in particle size distribution for microparticles 34-1 to 34-3. For example, the particle size may decrease from a distribution of largest microparticles 34-1 to a distribution of smallest microparticles 34-3. By having a variation in particle sizes, the microparticle layer 32 may exhibit monolayer, bilayer, and/or tri-layer packing of several distributions of microparticles 34-1 to 34-3. In certain embodiments, the distribution of largest microparticles 34-1 that may promote larger numbers of internal reflections may be generally arranged closer to the lumiphoric material layer 16 than the other distributions of microparticles 34-2, 34-3. Accordingly, light from the LED chip 12 and the lumiphoric material layer 16 may experience increased color mixing proximate the lumiphoric material, followed by further incremental color mixing with subsequent interactions with the distributions of smaller microparticles 34-2, 34-3. Additionally, arranging the distributions of smaller microparticles 34-2, 34-3 to effectively pack about the distribution of largest microparticles 34-1 reduces instances of light passing through the microparticle layer 32 without experiencing increased light recycling.

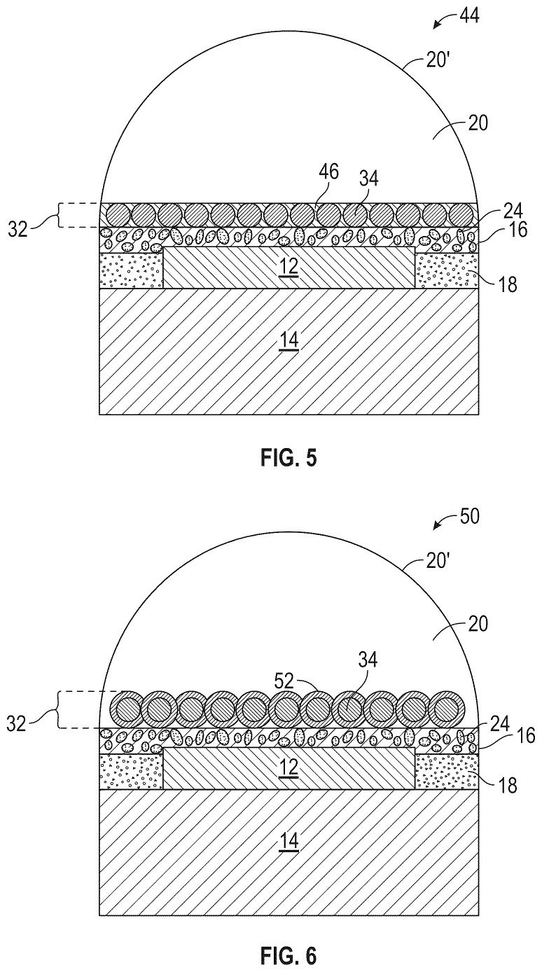

FIG. 5 is a cross-sectional view of an LED package 44 similar to the LED package 40 of FIG. 3 for embodiments where the microparticle layer 32 comprises a host material 46 that encapsulates the microparticles 34. As described above, the microparticle layer 32 may be deposited on the lumiphoric material layer 16 before the encapsulant 20 is formed. During deposition of the microparticle layer 32, such as spin coating or the like, the microparticles 34 may be deposited with the host material 46. The host material 46 may comprise a same or similar material as the encapsulant 20 in certain embodiments. In certain embodiments, the host material 46 may comprise a different material than the encapsulant 20 and/or a different index of refraction than the encapsulant 20. By forming the host material 46 with a different index of refraction, an increased mismatch between index of refraction values of the encapsulant 20 and the microparticle layer 32 may promote increased light refractions and color mixing within the microparticle layer 32. In certain embodiments, the host material 46 comprises silicone, TiO₂, SiO₂, and/or Al₂O₃ and the host material 46 may be deposited by atomic layer deposition. In still further embodiments, the host material 46 may have a graded index of refraction that grades from an index of refraction the same or close to that of the lumiphoric material layer 16 to an index of refraction the same or close to that of the encapsulant 20. Such an arrangement may reduce reflections at the interface between the lumiphoric material layer 16 and the microparticle layer 32. When formed by atomic layer deposition, the gradient index of refraction may be formed by progressively changing the stoichiometry for various atomic layers during deposition. In still further embodiments, the presence of the host material 46 may permit omission of the encapsulant 20, thereby forming a light-exiting surface for the LED package 44 along a top surface of the microparticle layer 32.

FIG. 6 is a cross-sectional view of an LED package 50 similar to the LED package 40 of FIG. 3 for embodiments where the microparticles 34 comprise a coating 52 on each microparticle 34. The coating 52 may comprise a thin dielectric film with a different material than the encapsulant 20, such as TiO₂, SiO₂, and/or Al₂O₃, among others. The coating 52 may serve to provide an index of refraction step with the encapsulant 20 and/or hold the microparticles 34 in place. In certain embodiments, the coating 52 may be formed on the microparticles 34 after they are positioned on the lumiphoric material layer 16, such as by atomic layer deposition. Accordingly, the coating 52 may effectively anchor the microparticles 34 in place over the LED chip 12. In such embodiments, the encapsulant 20 may be optional depending on the desired emission pattern for the LED package 50. In one example, the encapsulant 20 of FIG. 6 is omitted such that a light-exiting surface for the LED package 50 is formed along a top surface of the microparticle layer 32 along the coating 52. In still further embodiments, the coating 52 may be formed on each microparticle 34 before positioning the microparticles 34 on the lumiphoric material layer 16. Accordingly, the coating 52 may form an outer shell for each microparticle 34.

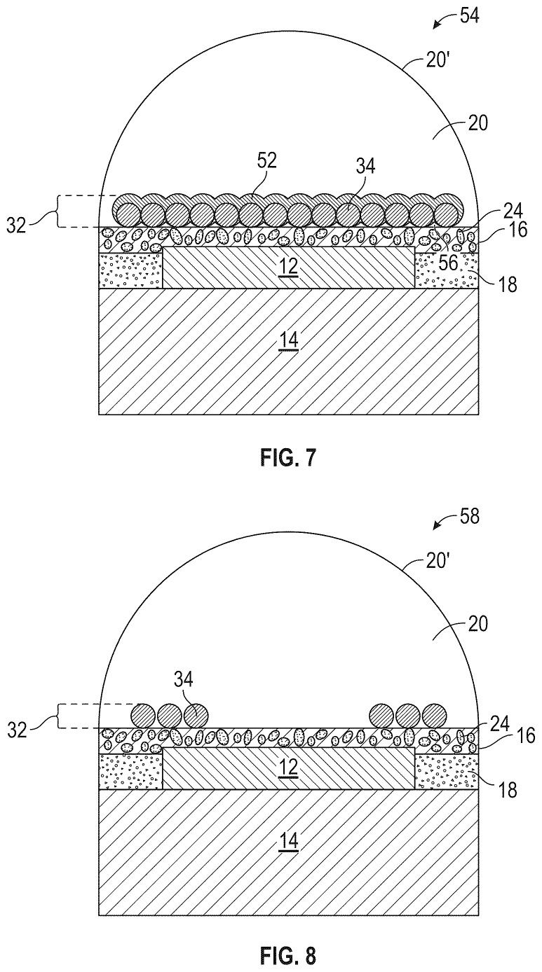

FIG. 7 is a cross-sectional view of an LED package 54 similar to the LED package 50 of FIG. 6 for embodiments where the coating 52 is formed on the microparticles 34 after the microparticles 34 are positioned on the lumiphoric material layer 16. In such embodiments, the microparticles 34 are placed on the lumiphoric material layer 16, followed by deposition of the coating 52. In one example, the coating 52 may be deposited by a line-of-sight deposition technique such as electron beam deposition. Accordingly, the coating 52 may effectively cover top surfaces of the microparticles 34 to secure the microparticles 34 in place. In turn, material of the later formed encapsulant 20 may not wick between and/or below the microparticles 34, which could lead to unintended repositioning of microparticles 34. In certain embodiments, the encapsulant 20 may bound perimeter edges of the microparticle layer 32 and one or more air gaps 56 may form between the microparticles 34 and the lumiphoric material layer 16. When present, the air gaps 56 may promote further light redirection and/or color mixing. In other embodiments, the encapsulant 20 may be optional depending on the desired emission pattern for the LED package 54. For example, the encapsulant 20 of FIG. 7 may be omitted such that a light-exiting surface for the LED package 54 is formed along a top surface of the microparticle layer 32 along the coating 52.

FIG. 8 is a cross-sectional view of an LED package 58 similar to the LED package 40 of FIG. 3 for embodiments where the microparticles 34 are patterned as localized regions on portions of the lumiphoric material layer 16. In certain embodiments, the microparticles 34 may be positioned only on certain regions of the lumiphoric material layer 16 to provide localized color mixing. For example, the microparticles 34 may be positioned on portions of the lumiphoric material layer 16 that are proximate perimeter edges of the LED chip 12 while other portions of the lumiphoric material layer 16 that are on central portions of the LED chip 12 may be devoid of the microparticles 34. Accordingly, light paths with wide angles may be subjected to improved color mixing to reduce color over angle variations and better match light paths normal to the surface of the LED chip 12.

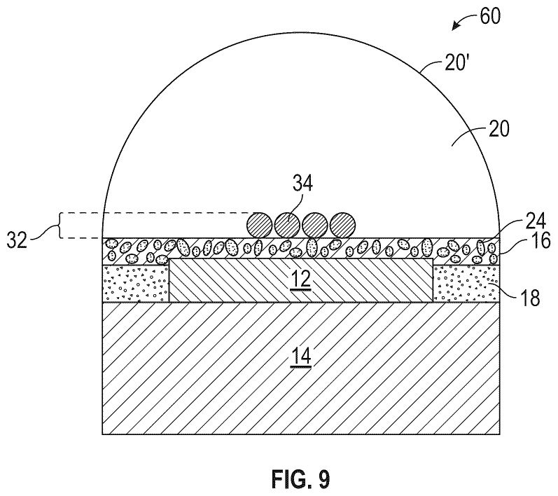

FIG. 9 is a cross-sectional view of an LED package 60 similar to the LED package 58 of FIG. 8 for embodiments where the microparticles 34 form an alternative pattern on the lumiphoric material layer 16. In FIG. 9, the localized region of the microparticles 34 is formed on surfaces of the lumiphoric material layer 16 that are on central portions of the LED chip 12, and other surfaces of the lumiphoric material layer 16 that are proximate perimeter edges of the LED chip 12 are devoid of microparticles 34. In this manner, light paths with shallower and/or normal angles relative to the LED chip 12 may be subjected to improved color mixing to reduce color over angle variations and better match light paths with wider angles.

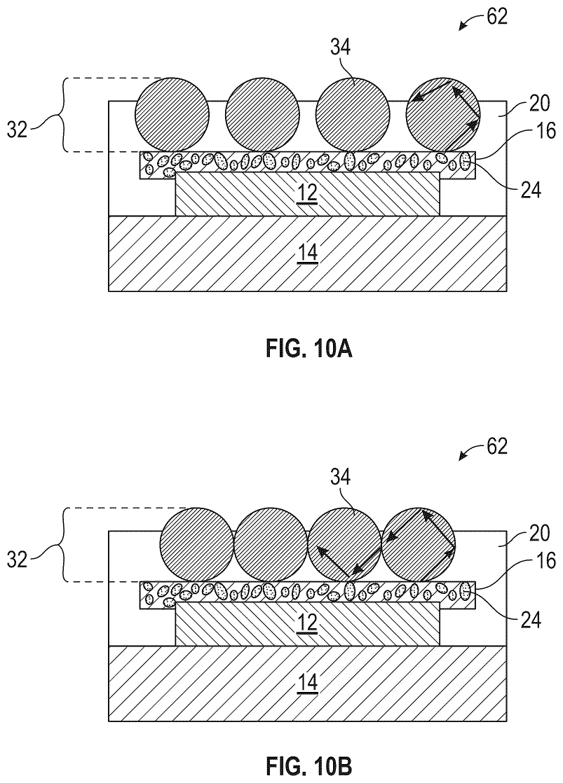

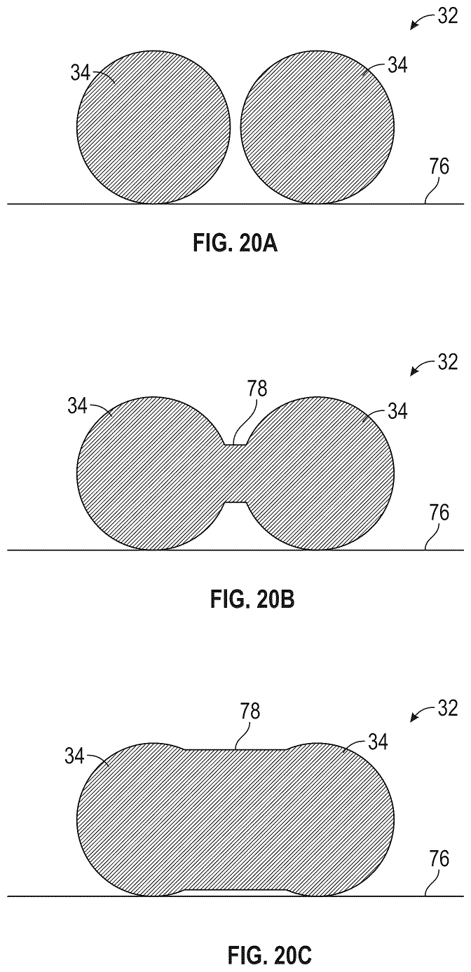

FIG. 10A is a cross-sectional view of an LED package 62 similar to the LED package 40 of FIG. 3 for embodiments where portions of the microparticles 34 are arranged to protrude out of the encapsulant 20. As described above, the microparticles 34 may be formed with average particle sizes in a range from 100 μm to 1000 μm. Larger average particle sizes may be employed so that one or more of the microparticles 34 may protrude past surfaces of the encapsulant 20. In certain embodiments, the microparticles 34 form a larger index of refraction mismatch with air than the encapsulant 20. Accordingly, increased internal reflections within each microparticle 34 may be realized for increased color mixing. FIG. 10B is a cross-sectional view of the LED package 62 of FIG. 10A for embodiments where one or more of the microparticles 34 are in contact with one another. In certain applications, it may be advantageous for direct contact between neighboring microparticles 34 to promote different emission profiles. For example, some light reflecting within one microparticle 34 may enter and internally reflect within a neighboring microparticle 34 before exiting the LED package 62. In certain embodiments, the microparticles 34 may initially be provided as separate particles in the LED package 62. After subsequent heat treatments, neighboring microparticles 34 may effectively merge together to form a continuous or monolithic structure of connected microparticles 34. An exemplary sequence for such embodiments is described below with reference to FIGS. 20A to 20C.

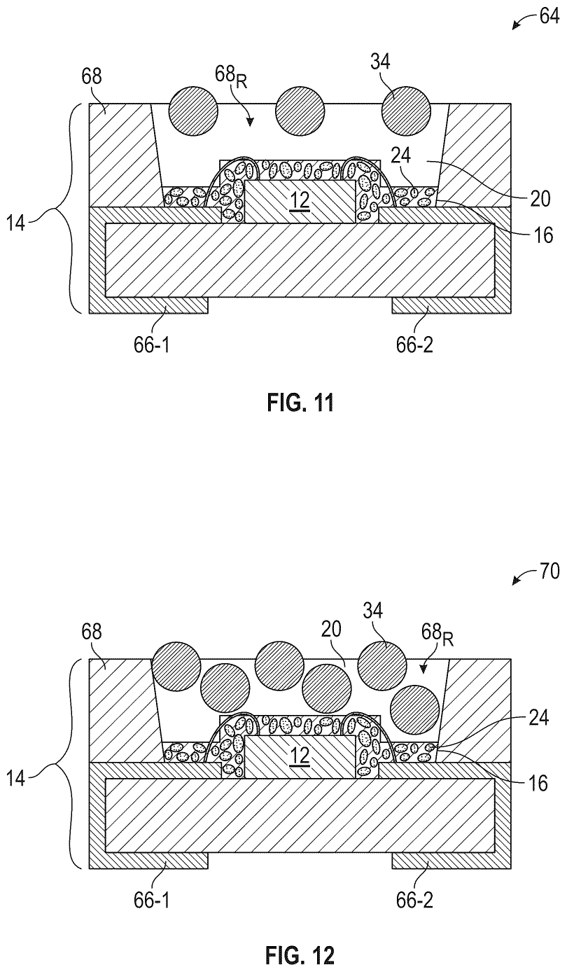

FIG. 11 is a cross-sectional view of an LED package 64 similar to the LED package 62 of FIGS. 10A and 10B for embodiments where the support element 14 comprises a lead frame structure. The lead frame structure includes a number of leads 66-1, 66-2 electrically coupled with the LED chip 12, and a housing 68 that encloses a portion of the leads 66-1, 66-2. The housing 68 forms a recess 68R and the LED chip 12 and lumiphoric material layer 16 are positioned proximate a floor of the recess 68R. The encapsulant 20 fills the recess 68R and effectively covers the LED chip 12 and lumiphoric material layer 16. The microparticles 34 are provided within portions of the encapsulant 20. In a similar manner as described above with respect to FIGS. 10A and 10B, portions of the microparticles 34 are arranged to extend and/or protrude out of a surface of the encapsulant 20 for improved light recycling and color mixing as light exits the encapsulant 20.

FIG. 12 is a cross-sectional view of an LED package 70 similar to the LED package 64 of FIG. 11 for embodiments where additional microparticles 34 are arranged within the encapsulant 20. As illustrated, certain microparticles 34 protrude out of the encapsulant 20 in a manner similar to FIG. 11 and other microparticles 34 are within the encapsulant 20 without extending out of the encapsulant 20. In certain embodiments, some of the microparticles 34 may be on or even directly on the lumiphoric material layer 16. Accordingly, enhanced light mixing may occur as light exits the lumiphoric material layer 16 and again before light exits the encapsulant 20.

FIG. 13 is a cross-sectional view of an LED package 72 similar to the LED package 70 of FIG. 12 for embodiments wherein the microparticles 34 are arranged in a conformal manner on the lumiphoric material layer 16. In certain embodiments, the encapsulant 20 may entirely cover and encapsulate the microparticles 34. In this arrangement, enhanced light mixing may occur as light exits the lumiphoric material layer 16.

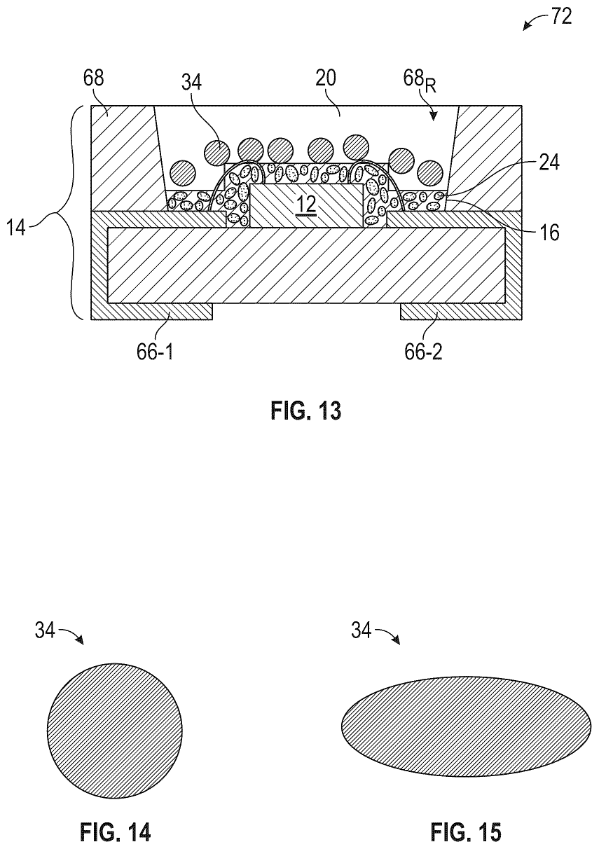

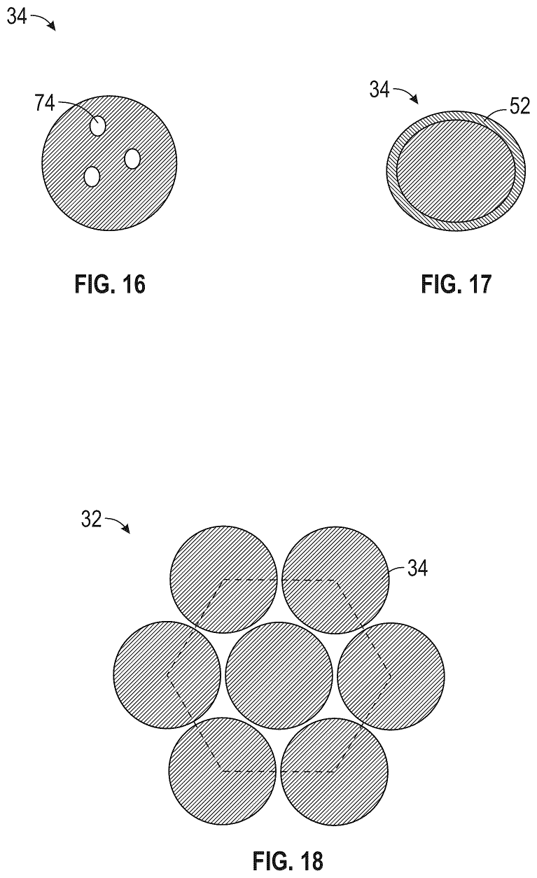

FIGS. 14 to 17 are cross-sectional views of various shapes of microparticles 34 according to principles of the present disclosure. The shapes depicted in FIGS. 14 to 17 may be implemented in any of the previously described embodiments with respect to FIGS. 2A to 13. Varying shapes of the microparticles 34 may tailor amounts and/or how long light recycling, color mixing, and/or whispering gallery mode occur to achieve targeted applications and emission profiles. FIG. 14 is a cross-sectional view for embodiments where the microparticle 34 forms a spherical shape, such as a microsphere. FIG. 15 is a cross-sectional view for embodiments where the microparticle 34 forms an oblong shape, such as an oval shape. FIG. 16 is a cross-sectional view for embodiments where the microparticle 34 includes one or more internal voids 74. In this manner, the microparticle 34 of FIG. 16 may embody a porous microparticle. The internal voids 74 may be sized to promote light scattering within the microparticle 34 in combination with light recycling for enhanced color mixing. In certain embodiments, the voids 74 form hollow voids within the microparticle 34. In other embodiments, the voids 74 may be formed by a material, such as a glass and/or ceramic bead. FIG. 17 is a cross-sectional view for embodiments where the microparticle 34 includes the coating 52 in the form of an outer shell in a similar manner as described above with respect to FIG. 6.

FIG. 18 is a top view of a layout of the microparticle layer 32 according to principles of the present disclosure. In embodiments, where the particle size of the microparticles 34 is generally uniform, the microparticles 34 may be tightly packed relative to one another. For example, the microparticles 34 may form microspheres in a hexagonally close packing arrangement as indicated by the superimposed dashed line hexagon in FIG. 18. Such tight packing of microparticles 34 promotes enhanced coverage of the underlying lumiphoric material layer 16 of FIGS. 2A to 13 for increased light recycling and mixing.

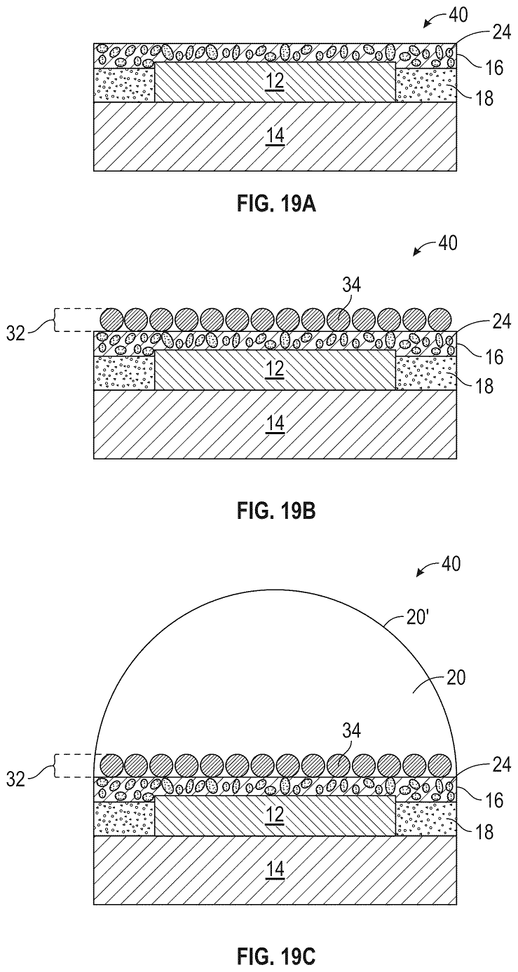

FIGS. 19A to 19C are cross-sectional views of the LED package 40 of FIG. 3 at various fabrication sequences illustrating formation of the microparticle layer 32 before the formation of the encapsulant 20. With such a sequence, precise placement of the microparticles 34 and corresponding microparticle layer 32 may be achieved and the subsequently formed encapsulant 20 may serve to encapsulate and anchor the microparticle layer 32 in place. The support element 14 of FIGS. 19A to 19C may embody a submount structure or a lead frame structure described above with respect to FIGS. 11 to 13.

FIG. 19A is a cross-sectional view of the LED package 40 of FIG. 3 at a fabrication step after the LED chip 12 is mounted to the support element 14, followed by formation of the light-altering material 18 and the lumiphoric material layer 16. In certain embodiments, the presence of the light-altering material 18 is optional. In further embodiments, the presence of the lumiphoric material layer 16 may also be optional. FIG. 19B is a cross-sectional view of the LED package 40 of FIG. 19A at a subsequent fabrication step where the microparticle layer 32 is formed. As described above, the microparticle layer 32 may be deposited by various techniques, including spin coating and/or atomic layer deposition of the various coating layers of FIGS. 6 and 7. In certain embodiments, the microparticle layer 32 may be deposited concurrently with the host material 46 of FIG. 5. While FIG. 19B illustrates the microparticle layer 32 as illustrated by FIG. 3, the arrangement of the microparticle layer 32 may be provided according to any of the embodiments described above with respect to FIGS. 2A to 18. In certain embodiments, one or more of the microparticles 34 may be partially embedded in the lumiphoric material layer 16. FIG. 19C is a cross-sectional view of the LED package 40 of FIG. 19B at a subsequent fabrication step where the encapsulant 20 is formed on the previously formed microparticle layer 32. In certain embodiments, the encapsulant 20 may be molded to form the lens 20'. In other embodiments, the encapsulant 20 may be dispensed on the microparticle layer 32.

FIGS. 20A to 20C are cross-sectional views for forming the microparticle layer 32 of any of the previous embodiments where some microparticles 34 merge together. FIG. 20A is a cross-sectional view of the microparticle layer 32 at an initial fabrication step where neighboring microparticles 34 are spaced from one another. As illustrated, the microparticles 34 are positioned on a surface 76, which may generally represent any surface within an LED package, such as the lumiphoric material layer 16 described above for FIGS. 2A to 10B. In other embodiments, the surface 76 may be omitted and the microparticles 34 may be spaced apart from one another and suspended within the encapsulant 20 as described above for FIG. 11. FIG. 20B is a cross-sectional view of the microparticle layer 32 of FIG. 20A at a subsequent processing step where neighboring microparticles 34 begin to merge together. For example, with elevated temperatures, annealing and/or sintering of the microparticles 34 may begin a merging step where they join together. By way of example, a neck portion 78 is illustrated where the two microparticles 34 begin to join together. FIG. 20C is a cross-sectional view of the microparticle layer 32 of FIG. 20B with additional merging of microparticles 34. After sufficient heating, the microparticles 34 may form a continuous and/or monolithic solid. In certain embodiments, the resulting structure forms a highly dense solid material of the microparticles 34 for enhanced light recycling. In some instances, the locations of the individual microparticles 34 may be hard to differentiate with sufficient merging.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a support element;
an LED chip on the support element, the LED chip configured to emit light with a first peak wavelength;
a lumiphoric material layer on the LED chip, the lumiphoric material layer configured to convert at least a portion of the light of the first peak wavelength to light with a second peak wavelength that is different than the first peak wavelength; and
a microparticle layer on the lumiphoric material layer, the microparticle layer comprising a plurality of microparticles with an average particle size in a range from above 1 micron (μm) to 1000 μm.

2. The LED package of claim 1, further comprising an encapsulant on the microparticle layer.

3. The LED package of claim 2, wherein the encapsulant forms a lens over the LED chip, and the encapsulant further forms an extension that laterally extends from a boundary of the lens to a peripheral edge of the support element, and a portion of the microparticle layer is covered by the extension.

4. The LED package of claim 2, wherein the microparticle layer further comprises a host material and the plurality of microparticles is positioned within the host material, wherein the host material comprises a different index of refraction than the encapsulant.

5. The LED package of claim 2, further comprising a coating on the plurality of microparticles, wherein the coating comprises a different index of refraction than the encapsulant.

6. The LED package of claim 5, wherein the coating forms a dielectric shell on each microparticle of the plurality of microparticles.

7. The LED package of claim 5, wherein the plurality of microparticles are positioned between the coating and the lumiphoric material layer, and one or more air gaps are formed between the plurality of microparticles and the lumiphoric material layer.

8. The LED package of claim 2, wherein at least one microparticle of the plurality of microparticles is arranged to protrude out of a surface of the encapsulant.

9. The LED package of claim 1, wherein the plurality of microparticles forms a single monolayer for the microparticle layer.

10. The LED package of claim 9, wherein the plurality of microparticles are arranged with a hexagonal close packing arrangement for the single monolayer.

11. The LED package of claim 1, wherein:
the plurality of microparticles comprises a first distribution of microparticles and a second distribution of microparticles;
a first average particle size of the first distribution of microparticles is larger than a second average particle size of the second distribution of microparticles; and
the first distribution of microparticles is positioned closer to the lumiphoric material layer than the second distribution of microparticles.

12. The LED package of claim 1, wherein the plurality of microparticles comprises a plurality of microspheres.

13. The LED package of claim 1, wherein the plurality of microparticles comprise glass, polyethylene, polystyrene, or polymethyl methacrylate.

14. The LED package of claim 1, wherein the plurality of microparticles form at least one localized region of microparticles on a surface of the lumiphoric material layer, and another surface of the lumiphoric material layer is devoid of the plurality of microparticles.

15. The LED package of claim 1, wherein at least one microparticle of the plurality of microparticles comprises one or more internal voids.

16. The LED package of claim 1, wherein at least two microparticles of the plurality of microparticles are merged together.

17. The LED package of claim 1, wherein at least one microparticle of the plurality of microparticles is partially embedded within the lumiphoric layer.

18. A light-emitting diode (LED) package comprising:
a support element;
an LED chip on the support element, the LED chip configured to emit light with a first peak wavelength;
an encapsulant on the LED chip; and
a plurality of microparticles in the encapsulant, wherein at least one microparticle of the plurality of microparticles is arranged to protrude out of a surface of the encapsulant.

19. The LED package of claim 18, wherein an average particle size is in a range from above 100 micron (μm) to 1000 μm.

20. The LED package of claim 18, further comprising a lumiphoric material layer on the LED chip, the lumiphoric material layer configured to convert at least a portion of the light of the first peak wavelength to light with a second peak wavelength that is different than the first peak wavelength, wherein at least one other microparticle of the plurality of microparticles is in contact with the lumiphoric material layer.

21. The LED package of claim 18, wherein the support element comprises a lead frame structure.

22. The LED package of claim 18, wherein at least two microparticles of the plurality of microparticles are merged together.

23. A method of forming a light-emitting diode (LED) package, the method comprising:
mounting an LED chip on a support element, the LED chip configured to emit light with a first peak wavelength;
forming a lumiphoric material layer on the LED chip, the lumiphoric material layer configured to convert at least a portion of the light of the first peak wavelength to light with a second peak wavelength that is different than the first peak wavelength;
forming a microparticle layer on the lumiphoric material layer; and
forming an encapsulant on the microparticle layer after forming the microparticle layer.

24. The method of claim 23, wherein forming the microparticle layer comprises arranging a plurality of microparticles on the lumiphoric material layer and heating the plurality of microparticles such that at least two microparticles of the plurality of microparticles merge together.
